(19) United States
(12) Patent Application Publication
(10) Pub. No.: US 2026/0164714 A1
(43) Pub. Date: Jun. 11, 2026

(54) ELONGATED CONTACT STRUCTURES FOR SEMICONDUCTOR DEVICES

(71) Applicant: Taiwan Semiconductor Manufacturing Company, Ltd., Hsinchu (TW)

(72) Inventors: Shu-Wen CHEN, Taipei City (TW); Yu-Wei CHANG, Hsinchu City (TW); Te-Chih HSIUNG, Taipei City (TW); Chih-Yuan TING, Taipei City (TW); Chao-Cheng CHEN, Hsin-Chu (TW); Wen WANG, Taipei City (TW)

(73) Assignee: Taiwan Semiconductor Manufacturing Company, Ltd., Hsinchu (TW)

(21) Appl. No.: 18/972,168

(22) Filed: Dec. 6, 2024

(51) Int. Cl. H10D 30/67; H10D 30/00; H10D 30/01; H10D 62/10; H10D 84/01; H10D 84/83

(52) U.S. Cl. CPC H10D 30/6729; H10D 30/014; H10D 30/0198; H10D 30/501; H10D 30/6735; H10D 62/121; H10D 84/0149; H10D 84/832

(57) ABSTRACT

The present disclosure describes a method to form a semiconductor device having an elongated contact structure. The method includes forming a source/drain (S/D) structure on a substrate. A first side of the S/D structure is in contact with a first contact structure. The method further includes forming a patterned photoresist on a second side of the S/D structure. The second side is opposite to the first side and the patterned photoresist includes an opening having a first width along a first direction and a second width along a second direction. The method further includes etching the opening in the patterned photoresist along the first direction to increase the first width of the opening and forming a second contact structure in the opening. The second contact structure extends through the substrate and is in contact with the second side of the S/D structure.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having an elongated backside contact structure, in accordance with some embodiments.

FIGS. 2 and 3 illustrate cross-sectional views of a semiconductor device having an elongated backside contact structure, in accordance with some embodiments.

FIG. 4 illustrates a plane view of a semiconductor device having an elongated backside contact structure, in accordance with some embodiments.

FIG. 5 is a flow diagram of a method for fabricating a semiconductor device having an elongated backside contact structure, in accordance with some embodiments.

FIGS. 6-10 illustrate isometric and cross-sectional views of a semiconductor device having an elongated backside contact structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process improvements, which can have multiple challenges. For example, nanostructure transistor devices have been introduced in an effort to improve gate control by increasing gate-channel coupling, increase on-state current to off-state current ratio (Ion/Ioff), and reduce short-channel effects (SCEs). The nanostructure transistor devices can have front-side and backside contact structures to reduce the device area and the metal interconnect length, thus reducing parasitic capacitances and parasitic resistances and improving device performance. However, with scaled dimensions, the backside contact structures may not fully land on (e.g., make complete physical contact with) the source/drain (S/D) structures of the nanostructure transistors, which can increase the contact resistance, reduce device current, and decrease the device performance. Additionally, due to the limited distance between adjacent backside contact structures, the photoresist bridge window can be small and the dimensions of the backside contact structure can be difficult to control by the hard mask layer patterning and etching processes.

Various embodiments in the present disclosure provide methods for forming an elongated backside contact structure in a semiconductor device (e.g., a nanostructure transistor) and/or other semiconductor devices in an integrated circuit (IC). In some embodiments, a S/D structure can be formed on a substrate. A first side of the S/D structure can be in contact with a first contact structure. A patterned photoresist can be formed on a second side of the S/D structure. The second side can be opposite to the first side. The patterned photoresist can include an opening having a first width along a first direction and a second width along a second direction. The opening in the patterned photoresist can be etched along the first direction to increase the first width of the opening. A second contact structure can be formed in the opening of the patterned photoresist. The second contact structure can extend through the substrate and can be in contact with the second side of the S/D structure. In some embodiments, the patterned photoresist can be etched by implanted ions along the first direction. In some embodiments, the second contact structure can have an increased dimension along the first direction. In some embodiments, the second contact structure can fully land on the S/D structure. As a result, the contact resistance between the second contact structure and the S/D structure can be reduced by about 20% to about 30% and the device current can be increased. Additionally, with the well-controlled first width by the implanted ions, the second contact structure may not be bridged (e.g., in physical contact) with adjacent contact structures on the second side.

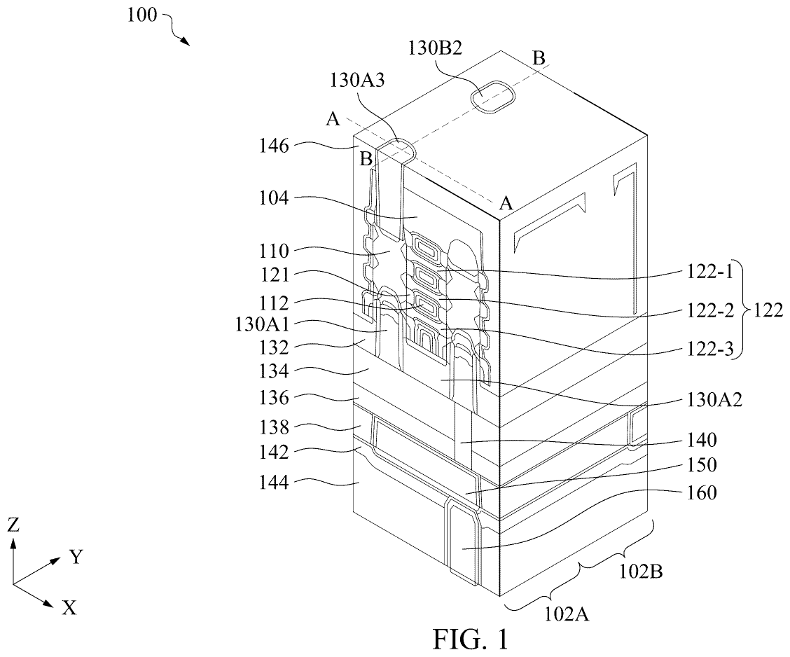

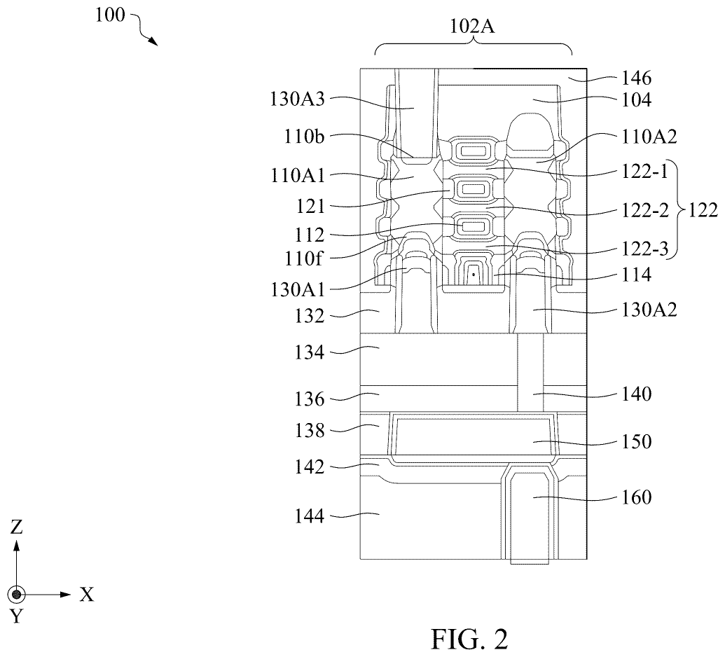

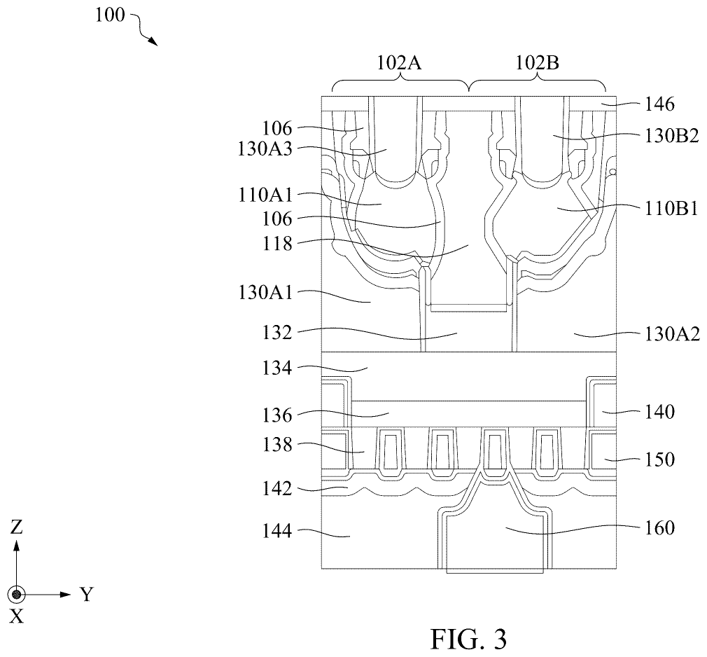

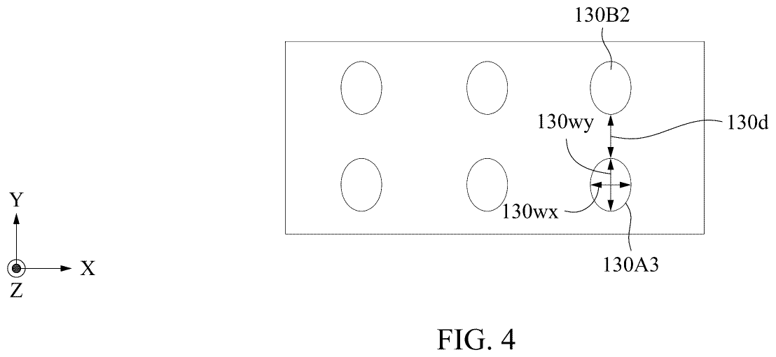

FIG. 1 illustrates an isometric view of a semiconductor device 100 having an elongated backside contact structure, in accordance with some embodiments. FIGS. 2 and 3 illustrate cross-sectional views of semiconductor device 100 across line A-A and line B-B shown in FIG. 1, respectively, in accordance with some embodiments. FIG. 4 illustrates a plane view of semiconductor device 100 having an elongated backside contact structure, in accordance with some embodiments. In some embodiments, semiconductor device 100 can include transistors 102A-102B, as shown in FIG. 1. In some embodiments, transistors 102A-102B can include nanostructure transistors. The nanostructure transistors can include the finFETs, the gate-all-around field effect transistor (GAA FET), the nanosheet transistor, the nanowire transistor, the multi-bridge channel transistor, the nano-ribbon transistor, and other similar structured transistors. The nanostructure transistors can provide a channel in a stacked nanosheet/nanowire configuration.

In some embodiments, transistors 102A-102B can be n-type field-effect transistors (NFETs). In some embodiments, transistors 102A-102B can be p-type field-effect transistors (PFETs). In some embodiments, any of transistors 102A-102B can be an NFET or a PFET. Though FIG. 1 shows two transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown in detail for simplicity. The discussion of elements of transistors 102A-102B with the same annotations applies to each other, unless mentioned otherwise. And like reference numerals generally indicate identical, functionally similar, and/or structurally similar elements.

Referring to FIGS. 1-3, semiconductor device 100 having transistors 102A-102B can be formed on a substrate 104 and can be isolated by shallow trench isolation (STI) regions 106. Transistors 102A-102B can include nanostructures 122-1, 122-2, and 122-3 (collectively referred to as “nanostructures 122”), gate structures 112, gate spacers 114, inner spacers 121, S/D structures 110A1, 110A2, and 110B1 (collectively referred to as “S/D structures 110”), etch stop layer (ESL) 116, interlayer dielectric (ILD) layer 118, and S/D contact structures 130A1, 130A2, 130B1, and 130B2 (collectively referred to as “S/D contact structures 130”).

Referring to FIGS. 1 and 2, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic). In some embodiments, substrate 104 can have a thickness ranging from about 10 nm to about 100 nm.

Referring to FIGS. 1-3, STI regions 106 can provide electrical isolation between transistors 102A-102B and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure. In some embodiments, STI regions 106 can have a thickness ranging from about 5 nm to about 50 nm.

Referring to FIGS. 1 and 2, nanostructures 122 can be formed on patterned portions of substrate 104. Embodiments of the nanostructures disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures.

As shown in FIGS. 1 and 2, nanostructures 122 can extend along an X-axis for transistors 102A-102B. In some embodiments, nanostructures 122 can be disposed on substrate 104. Nanostructures 122 can include a set of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102B. In some embodiments, nanostructures 122 can include semiconductor materials similar to or different from substrate 104. In some embodiments, nanostructures 122 can include silicon. In some embodiments, nanostructures 122 can include silicon germanium. The semiconductor materials of nanostructures 122 can be undoped or can be in-situ doped during their formation process. In some embodiments, as shown in FIGS. 1 and 2, nanostructures 122 under gate structures 112 can form channel regions of semiconductor device 100 and represent current carrying channel structures of semiconductor device 100. Though three layers of nanostructures 122 are shown in FIGS. 1 and 2, transistors 102A-102B can have any number of nanostructures 122.

S/D structures 110 can be disposed on substrate 104 and on opposing sides of nanostructures 122 and gate structures 112. S/D structures 110 can function as S/D regions of transistors 102A-102B. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions.

Referring to FIGS. 1 and 2, gate structures 112 can wrap around nanostructures 122. In some embodiments, gate structures 112 can include a gate dielectric layer, one or more work function metal layers, and a metal fill. In some embodiments, the gate dielectric layer can be multi-layered structures and can include an interfacial layer and a high-k dielectric layer. In some embodiments, the gate dielectric layer can include no interfacial layer and a high-k dielectric layer in direct contact with nanostructures 122. In some embodiments, the interfacial layer can include silicon oxide formed by a deposition process or an oxidation process. In some embodiments, the high-k dielectric layer can include hafnium oxide, zirconium oxide, or other suitable high-k dielectric materials.

In some embodiments, the one or more work function metal layers can include work function metals to tune the threshold voltage (Vₜ) of transistors 102A-102B. In some embodiments, gate structures 112 for NFET and PFET devices can have the same work function metal. In some embodiments, gate structures 112 for NFET and PFET devices can have different work function metals. In some embodiments, as shown in FIGS. 1 and 2, each of nanostructures 122 can be wrapped around by gate structures 112, for which gate structures 112 can be referred to as “gate-all-around (GAA) structures” and transistors 102A-102B can also be referred to as “GAA FETs 102A-102B.” The one or more work function metal layers can wrap around nanostructures 122 and can include work function metals to tune the Vₜ of transistors 102A-102B. In some embodiments, transistors 102A-102B can include any number of work function metal layers for Vₜ tuning (e.g., ultra-low Vₜ, low Vₜ, and standard Vₜ).

In some embodiments, NFETs 102A-102B can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102B can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work function values equal to or different from each other. In some embodiments, the metal fill can include titanium, tantalum, aluminum, cobalt, tungsten, nickel, ruthenium, or other suitable conductive materials.

Referring to FIGS. 1 and 2, gate spacers 114 can be disposed on sidewalls of gate structures 112 and inner spacers 121 can be disposed between gate structures 112 and S/D structures 110. Gate spacers 114 and inner spacers 121 can include insulating materials, such as silicon oxide, silicon nitride, silicon oxynitride, silicon carbonitride, silicon oxycarbide, silicon oxycarbonitride, a low-k material, and a combination thereof. Gate spacers 114 and inner spacers 121 can include a single layer or a stack of insulating layers. Gate spacers 114 and inner spacers 121 can have a low-k material with a dielectric constant less than about 3.9 (e.g., about 3.5, about 3.0, or about 2.8).

Referring to FIGS. 1-3, ESL 116 can be disposed on S/D structures 110 and sidewalls of gate spacers 114. ESL 116 can be configured to protect S/D structures 110 and gate structures 112 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

Referring to FIGS. 1-3, ILD layer 118 can be disposed on ESL 116 over S/D structures 110. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1-3, S/D contact structures 130A1 and 130A3 can be disposed on front-side 110f and backside 110b of S/D structures 110A1. S/D contact structures 130A2 can be disposed on the front-side 110f of S/D structures 110A2. S/D contact structures 130B2 can be disposed on backside 110b of S/D structures 110A2. In some embodiments, S/D contact structures 130 can include a silicide layer and a metal contact. In some embodiments, the silicide layer can include metal silicide and can provide a lower resistance interface between S/D contact structures 130 and S/D structures 110. Examples of metal used for forming the metal silicide include cobalt, titanium, and nickel. In some embodiments, the metal contact can include conductive materials, such as tungsten, aluminum, and cobalt. In some embodiments, S/D contact structures 130 can have a height along a Z-axis above S/D structures 110 ranging from about 10 nm to about 40 nm.

In some embodiments, as shown in FIG. 4, S/D contact structures 130A3 and 130B2 on backside 110b of S/D structures 110 (collectively referred to as “backside S/D contact structures 130”) can have an elongated geometric shape along a Y-axis, such as an ellipse and a rectangle, from a top-down view. In some embodiments, backside S/D contact structures 130 can have a width 130wx along an X-axis ranging from about 10 nm to about 30 nm. In some embodiments, backside S/D contact structures 130 can have a width 130wy along a Y-axis ranging from about 10 nm to about 100 nm. In some embodiments, width 130wy can be greater than width 130wx. In some embodiments, a ratio of width 130wy to width 130wx can range from about 1.05 to about 4.5. In some embodiments, profile angles between sidewall surfaces and bottom surfaces of backside S/D contact structures 130 along X-axis and Y-axis directions can range from about 85 degrees to about 90 degrees.

In some embodiments, if the profile angles are less than about 85 degrees, the ratio is less than about 1.05, width 130wx is less than about 10 nm, or width 130wy is less than about 10 nm, backside S/D contact structures 130 may not fully land on S/D structures 110, the contact resistance between backside S/D contact structures 130 and S/D structures 110 may increase, and the device current may decrease. If the ratio is greater than about 4.5, width 130wx is greater than about 30 nm, or width 130wy is greater than about 100 nm, backside S/D contact structures 130 may be short to adjacent gate structures 112 or adjacent backside S/D contact structures 130. With elongated backside S/D contact structures 130 having greater width 130wy along a Y-axis, backside S/D contact structures 130 can fully land on S/D structures 110. As a result, the contact resistance between backside S/D contact structures 130 and S/D structures 110 can be reduced by about 20% to about 30% and the device current can be increased. Additionally, with the well-controlled width 130wx and width 130wy by an ion implant process, backside S/D contact structures 130 may not be bridged with adjacent backside S/D contact structures.

In some embodiments, as shown in FIG. 4, a distance 130d between adjacent backside S/D contact structures 130A3 and 130B2 can range from about 20 nm to about 2 μm. A ratio between width 130wy to distance 130d can range from about 0.005 to about 0.5. If distance 130d is less than about 20 nm or the ratio is greater than about 0.5, backside contact structures 130 may be bridged to adjacent backside contact structures. If distance 130d is greater than about 2 μm or the ratio is less than about 0.005, backside S/D contact structures 130 may not fully land on S/D structures 110 and the contact resistance between backside S/D contact structures 130 and S/D structures 110 may increase.

In some embodiments, as shown in FIGS. 1-3, semiconductor device 100 can further include metal via 140, metal lines 150 and 160, capping layer 132, ESLs 136 and 142, and dielectric layers 134, 138, 144, and 146. In some embodiments, as shown in FIGS. 1-3, S/D contact structure 130A2, metal via 140, and metal lines 150 and 160 can connect front-side 110f of S/D structure 110A2 to other parts of semiconductor device 100 and/or other semiconductor devices in the IC of semiconductor device 100. In some embodiments, metal via 140 and metal lines 150 and 160 can include any suitable conductive materials, such as tungsten, copper, aluminum, cobalt, titanium, ruthenium, titanium nitride, tantalum nitride, and other suitable conductive materials. Metal via 140 and metal lines 150 and 160 can extend through ESLs 136 and 142 and dielectric layers 134, 138, and 144 to be electrically connected to S/D contact structures 130A2.

In some embodiments, ESLs 136 and 142 can include, for example, silicon oxide, silicon nitride, silicon oxynitride, silicon carbide, silicon carbonitride, boron nitride, silicon boron nitride, silicon carbon boron nitride, or a combination thereof. In some embodiments, ESLs 136 and 142 can include a same dielectric material or different dielectric materials. In some embodiments, dielectric layers 134, 138, 144, and 146 can include a dielectric material, such as silicon oxide, silicon nitride, silicon oxycarbide, silicon carbonitride, silicon oxynitride, silicon oxynitricarbide, and a combination thereof. In some embodiments, dielectric layers 134, 138, 144, and 146 can include a same dielectric material or different dielectric materials. In some embodiments, dielectric layer 146 can include silicon nitride and can have a thickness ranging from about 1 nm to about 15 nm.

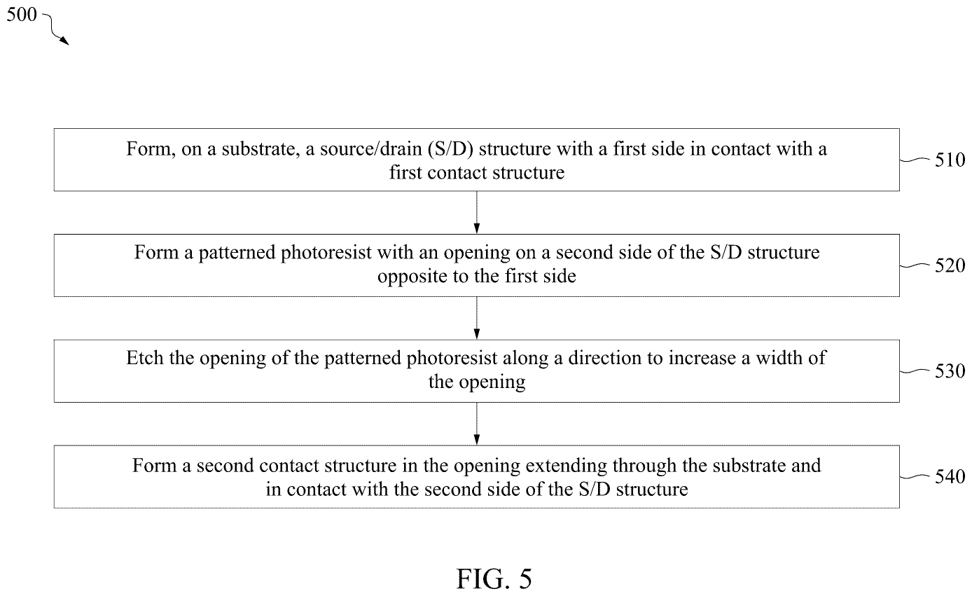

FIG. 5 is a flow diagram of a method 500 for fabricating semiconductor device 100 having an elongated backside contact structure, in accordance with some embodiments. Method 500 may not be limited to nanostructure transistor devices and can be applicable to other devices that would benefit from the elongated contact structures. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

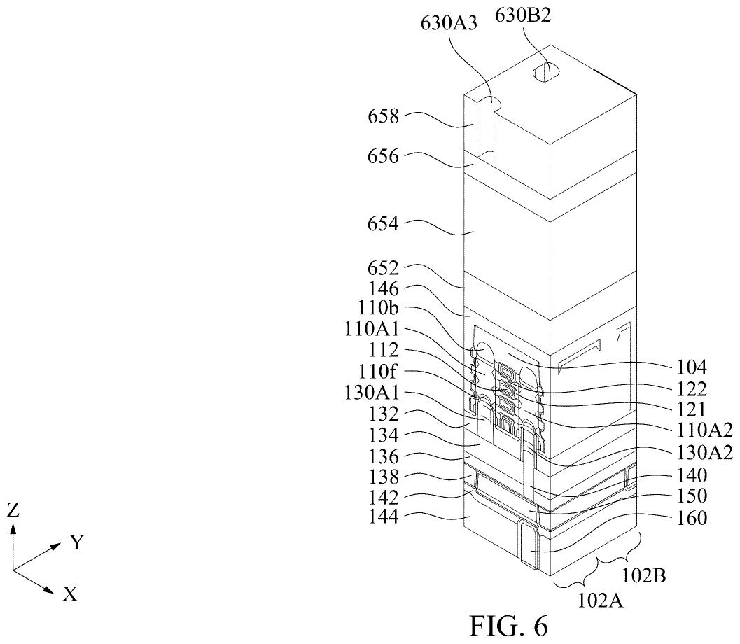

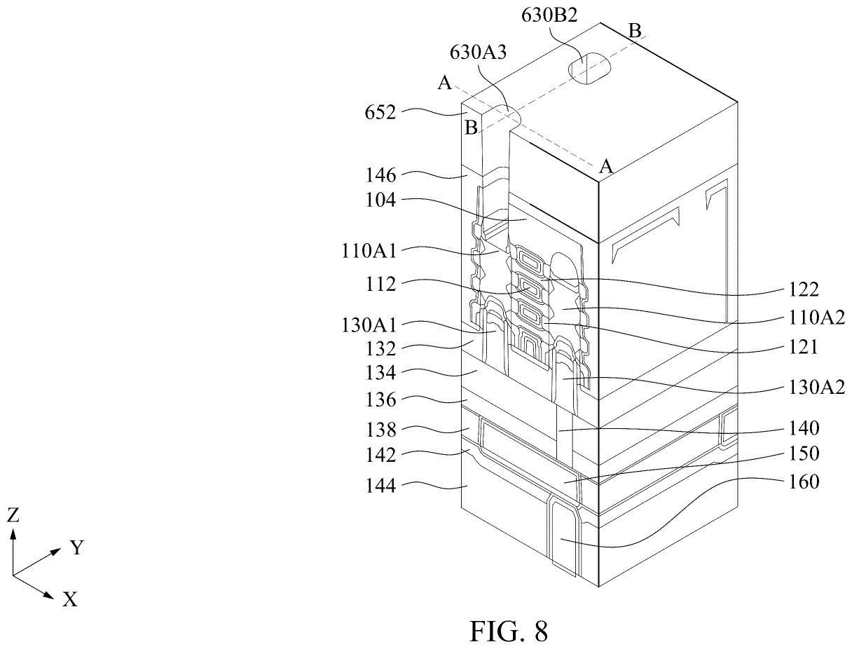

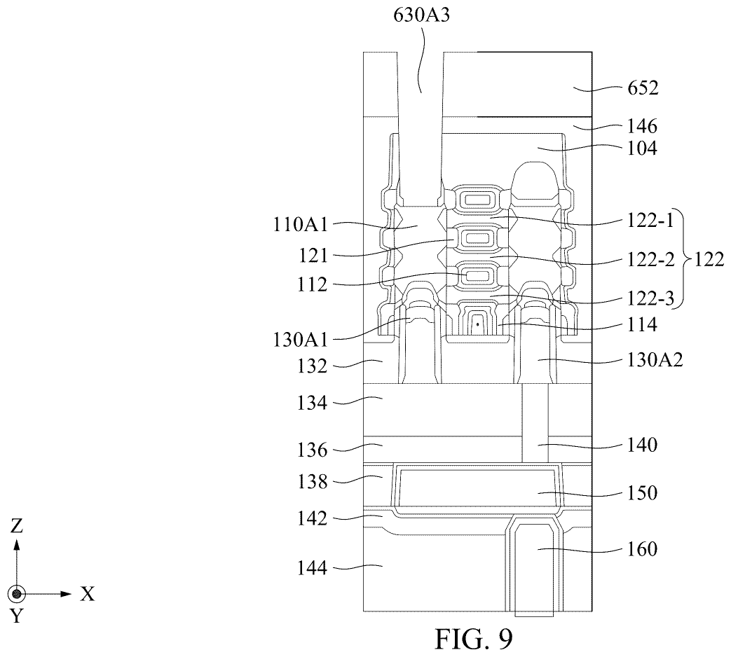

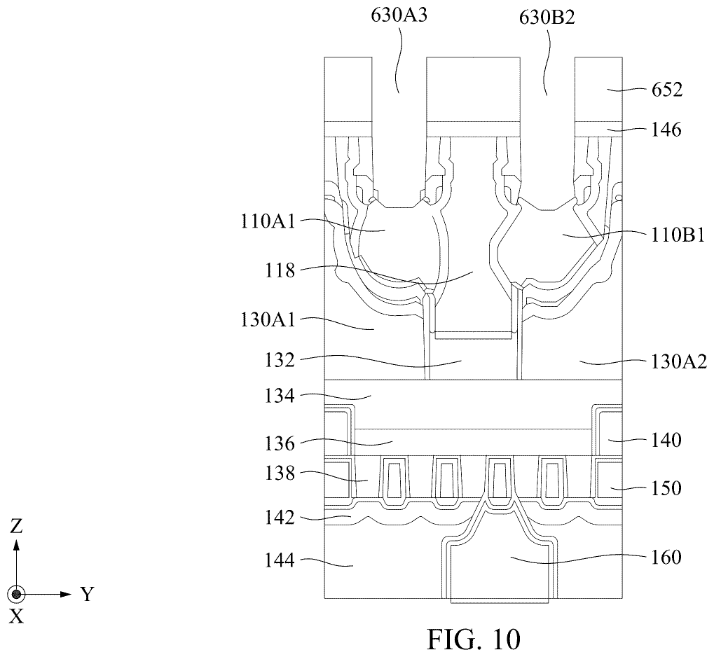

For illustrative purposes, the operations illustrated in FIG. 5 will be described with reference to the example fabrication process for fabricating semiconductor device 100 as illustrated in FIGS. 6-10. FIGS. 6-10 illustrate isometric and cross-sectional views of semiconductor device 100 having an elongated backside contact structure at various stages of its fabrication, in accordance with some embodiments. FIGS. 6-8 illustrate partial isometric views of semiconductor device 100 at various stages of its fabrication, in accordance with some embodiments. FIGS. 9 and 10 illustrate partial cross-sectional views of semiconductor device 100 along lines A-A and B-B, respectively, as shown in FIG. 8 at various stages of its fabrication, in accordance with some embodiments. Elements in FIGS. 6-10 with the same annotations as elements in FIGS. 1-4 are described above.

In referring to FIG. 5, method 500 begins with operation 510 and the process of forming, on a substrate, a source/drain structure with a first side in contact with a first contact structure. For example, as shown in FIG. 6, S/D structures 110A1 and 110A2 can be formed on substrate 104. Front-side 110f of S/D structures 110A1 and 110A2 can be in contact with contact structures 130A1 and 130A2, respectively. In some embodiments, transistors 102A-102B including S/D structures 110, gate structures 112, and nanostructures 122 can be formed on a front-side of substrate 104. In some embodiments, contact structures 130A1 and 130A2 can be formed on S/D structures 110A1 and 110A2. In some embodiments, as shown in FIG. 6, metal via 140 and metal lines 150 and 160 can be formed on S/D contact structure 130A2 to electrically connect S/D structure 110A2 to other parts of semiconductor device 100 and/or other semiconductor devices in the IC. In some embodiments, the operations to form transistors 102A-102B, metal via 140 and metal lines 150 and 160, ESLs 136 and 142, and dielectric layers 134, 138, 144, and 146 are not described in detail merely for clarity and ease of description.

Referring to FIG. 5, method 500 continues with operation 520 and the process of forming a patterned photoresist with an opening on a second side of the S/D structure opposite to the first side. For example, as shown in FIG. 6, patterned photoresist 658 with openings 630A3 and 630B2 can be formed on backside 110b of S/D structures 110. Backside 110b can be opposite to front-side 110f of S/D structures. In some embodiments, the formation of patterned photoresist 658 can include deposition of hard mask layer 652 on backside 110b of S/D structures 110, deposition of a stack of bottom layer 654, middle layer 656, and photoresist 658 on hard mask layer 652, and patterning of photoresist 658. In some embodiments, hard mask layer 652 can include silicon oxide and can have a thickness ranging from about 10 nm to about 100 nm. In some embodiments, the patterning process can include exposing photoresist 658 to a pattern, performing post-exposure bake processes, and developing photoresist 658 to form opening 630A3 and 630B2 in photoresist 658. In some embodiments, the developing process can include a wet etching process to remove a portion of photoresist 658 and form opening 630A3 and 630B2. In some embodiments, the wet etching/developing process can be referred to a “first removal process.” In some embodiments, after the wet etching process, opening 630A3 and 630B2 can have a circular shape or a rectangle shape. In some embodiments, opening 630A3 and 630B2 can be over S/D structures 110A1 and 110B1, respectively, to form contact structures on backside 110b of S/D structures 110A1 and 110B1.

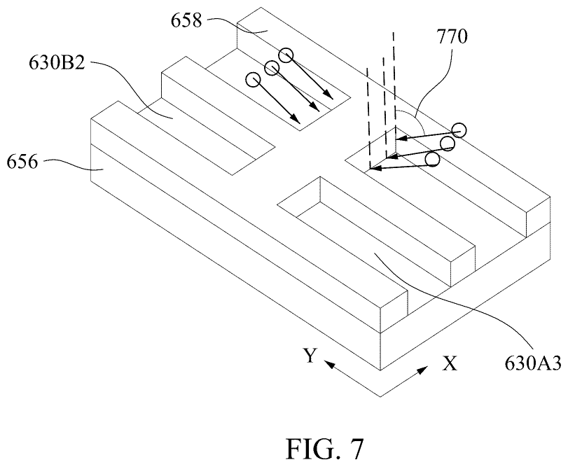

Referring to FIG. 5, in operation 530, the opening of the patterned photoresist can be etched along a direction to increase a width of the opening. For example, as shown in FIG. 7, openings 630A3 and 630B2 can be etched along a Y-axis direction to increase widths of openings 630A3 and 630B2 along the Y-axis direction. In some embodiments, openings 630A3 and 630B2 can be etched by an ion implant process. In some embodiments, the ion implant/etch process can be referred to as a “second removal process.” In some embodiments, the ion implant/etch process can remove or etch a portion of photoresist 658 around openings 630A3 and 630B2 along the Y-axis direction to increase a width of openings 630A3 and 630B2 along the Y-axis direction. In some embodiments, the ion implant/etch process can remove, etch, and/or densify the portion of photoresist 658 around openings 630A3 and 630B2 along the Y-axis direction to fine tune the width of openings 630A3 and 630B2 along the Y-axis direction. In some embodiments, the ion implant/etch process can increase the width of openings 630A3 and 630B2 along the Y-axis direction by about 3 nm to about 10 nm without increasing the width of openings 630A3 and 630B2 along the X-axis direction.

In some embodiments, the ion implant process can implant argon or xenon ions in photoresist 658. In some embodiments, an implant dose of the argon or xenon ions can range from about 4E14 cm⁻² to about 1.5E15 cm⁻². In some embodiments, the ion implant process can have an implant energy ranging from about 0.5 keV to about 1.5 keV. In some embodiments, as shown in FIG. 7, an implant angle 770 between a direction of the implant ions and a normal direction perpendicular to middle layer 656 or backside 110b of S/D structures 110 can range from about 10 degrees to about 90 degrees. If the implant dose is less than about 4E14 cm⁻², the implant energy is less than about 0.5 keV, or the implant angle is close to 90 degrees, the width of openings 630A3 and 630B2 may not be increased and the subsequently-formed S/D contact structures may not fully land on S/D structures 110. If the implant dose is greater than about 1.5E15 cm⁻², the implant energy is greater than about 1.5 keV, or the implant angle is less than about 10 degrees, openings 630A3 and 630B2 may be bridged and the subsequently-formed S/D contact structures may be bridged. In some embodiments, similar to subsequently-formed S/D contact structures 130A3 and 130B2 as illustrated in the plane view of FIG. 4, openings 630A3 and 630B2 can be elongated along the Y-axis direction by the ion implant process and can have an oval shape or a rectangular shape.

In some embodiments, as shown in FIGS. 8-10, the formation of elongated openings 630A3 and 630B2 in photoresist 658 can be followed by an etching process to remove middle layer 656, bottom layer 654, hard mask layer 652, dielectric layer 146, substrate 104, and a portion of S/D structures 110 under openings 630A3 and 630B2 to expose backside 110b of S/D structures 110. In some embodiments, the etching process can include a series of etching processes to remove each layer. In some embodiments, middle layer 656 and bottom layer 654 can be removed after elongated openings 630A3 and 630B2 are formed in hard mask layer 652. In some embodiments, a portion of S/D structures 110 can be removed during the etching process. In some embodiments, after the etching process, openings 630A3 and 630B2 can extend through hard mask layer 652, dielectric layer 146, and substrate 104 to expose S/D structures 110.

Referring to FIG. 5, in operation 540, a second contact structure is formed in the opening extending through the substrate and in contact with the second side of the S/D structure. For example, as shown in FIGS. 1-4, S/D contact structures 130A3 and 130B2 can be formed in openings 630A3 and 630B2. S/D contact structures 130A3 and 130B2 can extend through substrate 104 and can be in contact with backside 110b of S/D structures 110. In some embodiments, prior to the formation of S/D contact structures 130A3 and 130B2, hard mask layer 652 can be removed. In some embodiments, the formation of S/D contact structure 130A3 and 130B2 can include the formation of a silicide layer, the formation of a metal contact, and a chemical mechanical planarization (CMP) process.

In some embodiments, a conductive material can be blanket deposited in openings 630A3 and 630B2 and on dielectric layer 146 to fill openings 630A3 and 630B2. In some embodiments, the conductive material can include tungsten, aluminum, cobalt, or other suitable conductive material. In some embodiments, deposition of the conductive material can be followed by an anneal process to form the silicide layer. In some embodiments, the formation of the silicide layer and the metal contact can be followed by the CMP process to planarize top surfaces of dielectric layer 146 and S/D contact structure 130A3 and 130B2.

In some embodiments, as shown in FIGS. 1-4, S/D contact structure 130A3 and 130B2 can have an elongated geometric shape along a Y-axis, such as an ellipse and a rectangle, from a top-down view. In some embodiments, width 130wx along an X-axis of S/D contact structures 130A3 and 130B2 can range from about 10 nm to about 30 nm. In some embodiments, width 130wy along a Y-axis of S/D contact structures 130A3 and 130B2 can range from about 10 nm to about 100 nm. In some embodiments, width 130wy can be greater than width 130wx. In some embodiments, a ratio of width 130wy to width 130wx can range from about 1.05 to about 4.5. If the ratio is less than about 1.05, width 130wx is less than about 10 nm, or width 130wy is less than about 10 nm, S/D contact structure 130A3 and 130B2 may not fully land on S/D structures 110, the contact resistance between S/D structures 110 and S/D contact structure 130A3 and 130B2 may increase, and the device current may decrease. If the ratio is greater than about 4.5, width 130wx is greater than about 30 nm, or width 130wy is greater than about 100 nm, S/D contact structure 130A3 and 130B2 may be short to adjacent gate structures 112 or adjacent backside S/D contact structures 130. With elongated S/D contact structure 130A3 and 130B2 having greater width 130wy along a Y-axis, S/D contact structure 130A3 and 130B2 can fully land on S/D structures 110. As a result, the contact resistance between S/D structures 110 and S/D contact structure 130A3 and 130B2 can be reduced by about 20% to about 30% and the device current can be increased. Additionally, with the well-controlled width 130wx and width 130wy by the ion implant process, S/D contact structure 130A3 and 130B2 may not be bridged with adjacent backside S/D contact structures.

In some embodiments, method 500 and the ion implant/etch process can be used to form other contact structures, for example, front-side S/D contact structures 130A1 and 130A2. In some embodiments, method 500 and the ion implant/etch process can be used to form other structures that have a well-controlled change of a dimension of other structures along one or more directions. In some embodiments, method 500 and the ion implant/etch process can be used to fine tune the dimensions of the photoresist and masking layers on other structures to have a better control of a dimension of the other structures along various directions.

Various embodiments in the present disclosure provide methods for forming an elongated backside S/D contact structures 130A3 and 130B2 in semiconductor device 100. In some embodiments, S/D structures 110 can be formed on substrate 104. Front-side 110f of S/D structures 110 can be in contact with front-side S/D contact structures 130A1 and 130A2. Patterned photoresist 658 can be formed on backside 110b of S/D structures 110. Backside 110b can be opposite to front-side 110f. Patterned photoresist 658 can include openings 630A3 and 630B2 having a first width along a Y-axis direction and a second width along an X-axis direction. Openings 630A3 and 630B2 in patterned photoresist 658 can be etched along the Y-axis direction to increase the first width of openings 630A3 and 630B2. S/D contact structures 130A3 and 130B2 can be formed in openings 630A3 and 630B2 of patterned photoresist 658. S/D contact structures 130A3 and 130B2 can extend through substrate 104 and can be in contact with backside 110b of S/D structures 110. In some embodiments, patterned photoresist 658 can be removed/etched by implanted ions. In some embodiments, S/D contact structures 130A3 and 130B2 can have an increased dimension along the Y-axis. In some embodiments, S/D contact structures 130A3 and 130B2 can fully land on S/D structures 110. As a result, the contact resistance between S/D structures 110 and S/D contact structures 130A3 and 130B2 can be reduced by about 20% to about 30% and the device current of semiconductor device 100 can be increased. Additionally, with the well-controlled first width by the implanted ions, S/D contact structures 130A3 and 130B2 may not be bridged with adjacent contact structures on backside 110b of S/D structures 110.

In some embodiments, a method includes forming a source/drain (S/D) structure on a substrate. A first side of the S/D structure is in contact with a first contact structure. The method further includes forming a patterned photoresist on a second side of the S/D structure. The second side is opposite to the first side and the patterned photoresist includes an opening having a first width along a first direction and a second width along a second direction. The method further includes etching the opening in the patterned photoresist along the first direction to increase the first width of the opening and forming a second contact structure in the opening. The second contact structure extends through the substrate and is in contact with the second side of the S/D structure.

In some embodiments, a method includes forming a transistor on a substrate. The transistor includes a source/drain (S/D) structure connected with a first contact structure on a first side of the S/D structure. The method further includes depositing a photoresist on a second side of the S/D structure. The second side is opposite to the first side. The method further includes patterning the photoresist to form an opening using a first removal process, increasing a dimension of the opening with a second removal process different than the first removal process, and forming a second contact structure in the second opening. The second contact structure extends through the substrate and is in contact with the second side of the S/D structure.

In some embodiments, a semiconductor device includes a source/drain (S/D) structure on a substrate, a first contact structure in contact with a first side of the S/D structure, and a second contact structure extending through the substrate and in contact with a second side of the S/D structure. The second side is opposite to the first side. The second contact structure has a first width along a first direction and a second width along a second direction. The first direction is perpendicular to the second direction and the first width is greater than the second width.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a source/drain (S/D) structure on a substrate, wherein a first side of the S/D structure is in contact with a first contact structure;
forming a patterned photoresist on a second side of the S/D structure, wherein the second side is opposite to the first side and wherein the patterned photoresist comprises an opening having a first width along a first direction and a second width along a second direction;
etching the opening in the patterned photoresist along the first direction to increase the first width of the opening; and
forming a second contact structure in the opening, wherein the second contact structure extends through the substrate and is in contact with the second side of the S/D structure.

2. The method of claim 1, further comprising:
forming a dielectric layer on the second side of the S/D structure;
forming a hard mask layer on the dielectric layer; and
forming the patterned photoresist on the hard mask layer.

3. The method of claim 1, wherein etching the opening in the patterned photoresist comprises implanting argon ions towards the opening along the first direction.

4. The method of claim 1, wherein etching the opening in the patterned photoresist comprises removing a portion of the patterned photoresist along the first direction.

5. The method of claim 1, wherein etching the opening in the patterned photoresist comprises implanting the patterned photoresist with an implant energy ranging from about 0.5 keV to about 1.5 keV.

6. The method of claim 1, wherein etching the opening in the patterned photoresist comprises implanting the patterned photoresist with an implant dose ranging from about 4E14 cm⁻² to about 1.5E15 cm⁻².

7. The method of claim 1, wherein etching the opening in the patterned photoresist comprises implanting the patterned photoresist with an implant angle between a third direction of implant ions and a fourth direction perpendicular to the second side of the S/D structure, and wherein the implant angle ranges from about 10 degrees to about 90 degrees.

8. The method of claim 1, wherein forming the second contact structure comprises:
removing a portion of the S/D structure on the second side;
depositing the second contact structure on the second side of the S/D structure; and
performing a planarization process on the second contact structure.

9. A method, comprising:
forming a transistor on a substrate, wherein the transistor comprises a source/drain (S/D) structure connected with a first contact structure on a first side of the S/D structure;
depositing a photoresist on a second side of the S/D structure, wherein the second side is opposite to the first side;
patterning the photoresist to form an opening using a first removal process;
increasing a dimension of the opening with a second removal process different than the first removal process; and
forming a second contact structure in the second opening, wherein the second contact structure extends through the substrate and is in contact with the second side of the S/D structure.

10. The method of claim 9, further comprising:
forming a dielectric layer on the second side of the S/D structure;
forming a hard mask layer on the dielectric layer; and
forming the photoresist on the hard mask layer.

11. The method of claim 9, wherein increasing the dimension of the opening with the second removal process comprises implanting argon ions towards the opening along one direction.

12. The method of claim 9, wherein increasing the dimension of the opening with the second removal process comprises removing a portion of the photoresist around the opening along a direction of implanted ions.

13. The method of claim 9, wherein increasing the dimension of the opening with the second removal process comprises implanting the photoresist around the opening with an implant energy ranging from about 0.5 keV to about 1.5 keV.

14. The method of claim 9, wherein increasing the dimension of the opening with the second removal process comprises implanting the photoresist around the opening with an implant dose ranging from about 4E14 cm⁻² to about 1.5E15 cm⁻².

15. The method of claim 9, wherein the first removal process comprises a wet etching process and the second removal process comprises an ion etching process.

16. A semiconductor device, comprising:
a source/drain (S/D) structure on a substrate;
a first contact structure in contact with a first side of the S/D structure; and
a second contact structure extending through the substrate and in contact with a second side of the S/D structure, wherein:
the second side is opposite to the first side;
the second contact structure has a first width along a first direction and a second width along a second direction;
the first direction is perpendicular to the second direction; and
the first width is greater than the second width.

17. The semiconductor device of claim 16, wherein a ratio of the first width to the second width ranges from about 1.05 to about 4.5.

18. The semiconductor device of claim 16, wherein the second contact structure has an elongated geometric shape of an ellipse.

19. The semiconductor device of claim 16, further comprising a dielectric layer on the substrate at the second side of the S/D structure, wherein top surfaces of the dielectric layer and the second contact structure are co-planar.

20. The semiconductor device of claim 16, further comprising a plurality of nanostructures along the first direction, wherein the plurality of semiconductor layers are in contact with the S/D structure.
